(19) United States
(12) Patent Application Publication
(10) Pub. No.: US 2026/0202759 A1
(43) Pub. Date: Jul. 16, 2026

(54) APPARATUS AND METHOD FOR PREDICTING AERIAL IMAGES IN SEMICONDUCTOR LITHOGRAPHY PROCESSES

(71) Applicant: SEOUL NATIONAL UNIVERSITY R&DB FOUNDATION, Seoul (KR)

(72) Inventors: Do-Nyun KIM, Seoul (KR); Jinho LEE, Hwaseong-si (KR); Seoungwoo LEE, Gimpo-si (KR)

(21) Appl. No.: 19/438,746

(22) Filed: Jan. 2, 2026

(30) Foreign Application Priority Data
Jan. 15, 2025 (KR) 10-2025-0005874

(51) Int. Cl. G03F 7/00; G06T 7/00; G06V 10/82

(52) U.S. Cl. CPC G03F 7/706841; G03F 7/70666; G06T 7/001; G06V 10/82; G06T 2207/20048; G06T 2207/20081; G06T 2207/20084; G06T 2207/30148

(57) ABSTRACT

An aerial image prediction apparatus for predicting an aerial image in a semiconductor lithography process according to an embodiment includes a memory in which an aerial image prediction program is stored and a processor configured to execute the program stored in the memory. The aerial image prediction program inputs positional information of a region of interest on a photomask into a physics-informed neural network-based learning model to predict an aerial image representing a light intensity distribution irradiated onto a photoresist layer after passing through the region of interest.

### CROSS-REFERENCE TO RELATED APPLICATION

This application claims the benefit under 35 USC 119 (a) of Korean Patent Application No. 10-2025-0005874 filed on Jan. 15, 2025 in the Korean Intellectual Property Office, the entire disclosure of which is incorporated herein by reference for all purposes.

### BACKGROUND

### Field

The present invention relates to an apparatus and method for predicting aerial images in semiconductor lithography processes.

Semiconductor lithography is an essential process in the manufacture of integrated circuits and plays a crucial role in achieving precise patterning of semiconductor wafers. Two fundamental theories that form the basis of lithography technology are the theories of Abbe and Hopkins. Abbe's theory, based on the wave nature of light, explains the diffraction limit of optical systems. Abbe's equation defines that the minimum resolvable feature size in an optical system is determined by the wavelength of light and the numerical aperture (NA) of the system. This theory has been pivotal in the development of optical microscopy and subsequent photolithography technologies. Furthermore, Hopkins' theory extends Abbe's work by incorporating the effects of partial coherence in the imaging process. It addresses the fact that the light source used in practical lithography systems is not perfectly coherent, and provides a comprehensive framework for predicting and optimizing the performance of lithography systems, especially as they evolve to employ higher NA (numerical aperture) values and shorter wavelengths.

Recently, the semiconductor industry has adopted extreme ultraviolet (EUV) lithography, which utilizes light with a wavelength of 13.5 nm. Compared to the previously used deep ultraviolet (DUV) lithography, the significantly shorter wavelength enables finer patterning on semiconductor wafers, allowing continued device scaling in accordance with Moore's law. As EUV lithography continues to expand across various applications, the industry is now transitioning toward high-NA EUV lithography. High-NA systems exceeding an NA of 0.5 can ensure superior resolution and throughput necessary for the production of next-generation semiconductor devices. However, these advancements also present significant optical challenges. Because the accuracy of optical theories and models directly impacts device design, optimization, and manufacturing yield, the ability to predict optical behavior with precision has become increasingly important.

At the same time, research efforts have been growing to enhance the predictive capability of optical models using machine learning techniques. Among these approaches, attempts utilizing Physics-Informed Neural Networks (PINNs) have been reported. PINNs incorporate physical principles directly into the neural network training process, ensuring that the resulting model adheres to known physical laws and constraints. This approach contrasts with conventional neural networks, which often require large datasets and face difficulties in extrapolation beyond the training domain.

By embedding physical knowledge into the learning network, PINNs can achieve high accuracy with less data and deliver reliable predictions under new scenarios. Since PINNs leverage both data-driven and physics-based insights, they are expected to be particularly suitable for complex domains such as semiconductor lithography.

In the present invention, the PINN algorithm is applied to the Abbe and Hopkins models to improve the accuracy of EUV optical prediction. Through this, the invention aims to resolve the issues arising in high-NA EUV lithography.

### SUMMARY

A related prior art document includes Korean Patent Publication No. 10-2024-0016555 (Title: Lithography Model Simulation Method, Photomask Fabrication Method Using the Same, and Semiconductor Device Manufacturing Method Using the Same).

The present invention has been devised to solve the above-described problems, and an object of the present invention is to provide an apparatus and method for predicting aerial images in semiconductor lithography processes by using a learning model based on a physics-informed neural network (PINN).

However, the technical problem to be achieved by the embodiments of the present invention is not limited to the aforementioned problem, and various other technical objectives may also be achieved.

As a technical means for solving the above-described problem, an apparatus for predicting aerial images in semiconductor lithography processes according to an embodiment of the present invention comprises a memory in which an aerial image prediction program is stored, and a processor configured to execute the program stored in the memory. The aerial image prediction program is configured to input positional information of a region of interest on a photomask into a physics-informed neural network (PINN)-based learning model to predict an aerial image representing the intensity distribution of light irradiated onto a photoresist layer after passing through the region of interest. The learning model based on the physics-informed neural network comprises: a fully connected neural network trained to infer a first aerial image corresponding to the positional information of the region of interest; and a physics-informed neural network configured to convert the first aerial image into frequency-domain data through Fourier transformation, apply the frequency-domain data to a mathematical model based on an Abbe model or a Hopkins model to calculate a second aerial image, and update weights of the fully connected neural network using a loss function representing a difference between the first aerial image and the second aerial image.

According to another embodiment of the present invention, a method for predicting aerial images in semiconductor lithography processes performed by the aerial image prediction apparatus comprises: receiving positional information of a region of interest on a photomask; and predicting an aerial image representing the intensity distribution of light irradiated onto a photoresist layer after passing through the region of interest, by inputting the positional information of the region of interest into a physics-informed neural network (PINN)-based learning model. The learning model based on the physics-informed neural network comprises a fully connected neural network trained to infer a first aerial image corresponding to the positional information of the region of interest, and a physics-informed neural network configured to convert the first aerial image into frequency-domain data through Fourier transformation, apply the frequency-domain data to a mathematical model based on an Abbe model or a Hopkins model to calculate a second aerial image, and update the weights of the fully connected neural network using a loss function representing a difference between the first aerial image and the second aerial image.

According to at least one of the technical means for solving the above problems, the invention significantly improves computational efficiency and accuracy in aerial image prediction for EUV lithography, enabling real-time simulation within a few seconds. Furthermore, by integrating physical laws into the neural network, the invention enhances patterning accuracy on semiconductor wafers, minimizes defects, and improves manufacturing yield.

### BRIEF DESCRIPTION OF THE DRAWINGS

FIG. 1 is a diagram for explaining an aerial image in a semiconductor lithography process to be predicted by the present invention, together with the Abbe model and the Hopkins model.

FIGS. 2A and 2B are diagrams illustrating a general lithography process, and comparing lithography results without optical proximity correction (OPC) and lithography results with OPC applied.

FIG. 3 is a diagram illustrating an aerial image prediction apparatus according to an embodiment of the present invention.

FIG. 4 is a diagram illustrating the configuration of a learning model based on a physics-informed neural network according to an embodiment of the present invention.

FIGS. 5 and 6 are diagrams for explaining pattern types of a photomask applied in an embodiment of the present invention.

FIGS. 7A and 7B are diagrams illustrating examples of aerial images output through the aerial image prediction apparatus according to an embodiment of the present invention.

FIG. 8 is a flowchart illustrating a method for predicting aerial images according to an embodiment of the present invention.

### DETAILED DESCRIPTION

Hereinafter, embodiments of the present invention will be described in detail with reference to the accompanying drawings so that those skilled in the art can easily carry out the invention. However, the present invention may be implemented in various different forms and is not limited to the embodiments described herein. In the drawings, parts irrelevant to the description of the invention are omitted for clarity, and like reference numerals denote like elements throughout the specification.

In the entire specification, when a part is described as being “connected” to another part, this not only includes a case of “direct connection” but also includes a case of being “electrically connected” through another element interposed therebetween. In addition, when a part is described as “including” a certain component, it means that other components may be further included unless specifically stated otherwise.

In the present specification, the term “unit” refers to a module implemented by hardware, a module implemented by software, or a module implemented using both. One unit may be realized by two or more hardware elements, or two or more units may be realized by a single hardware element. The expression “-unit” is not limited to software or hardware, and may be implemented as a component stored in an addressable storage medium or configured to execute one or more processors. For example, a “-unit” may include software components, object-oriented software components, class components, task components, processes, functions, attributes, procedures, subroutines, segments of program code, drivers, firmware, microcode, circuits, data, databases, data structures, tables, arrays, and variables. The functions provided within the components and “units” may be combined into a smaller number of components or “units” or divided into additional components or “units.” Furthermore, the components and “units” may be implemented to execute one or more CPUs within a device.

The term “network” refers to a connection structure that allows information exchange between nodes such as terminals and servers, and includes a local area network (LAN), a wide area network (WAN), the Internet (World Wide Web), wired or wireless data communication networks, telephone networks, and wired or wireless television communication networks.

Examples of wireless data communication networks include 3G, 4G, 5G, 3GPP (3rd Generation Partnership Project), LTE (Long Term Evolution), WiMAX (World Interoperability for Microwave Access), Wi-Fi, Bluetooth communication, infrared communication, ultrasonic communication, visible light communication (VLC), and LiFi, but are not limited thereto.

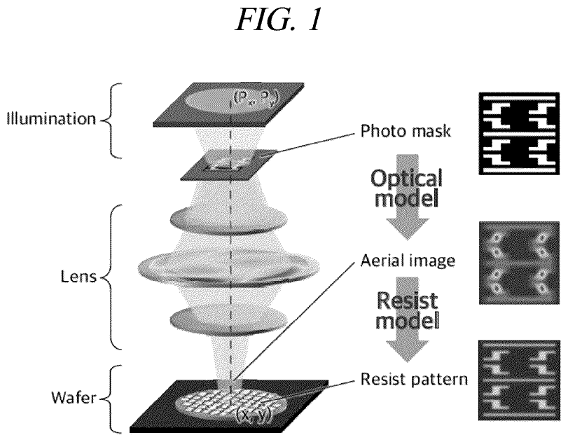

FIG. 1 is a diagram for explaining an aerial image in a semiconductor lithography process to be predicted by the present invention, together with the Abbe model and the Hopkins model.

Photolithography is a process for transferring complex circuit patterns onto a silicon wafer and generally includes exposing a photoresist layer on the wafer to light through a mask containing the desired circuit design. However, due to the wave nature of light, the precision of such patterns is limited by diffraction and other optical constraints when the pattern is projected onto the wafer.

To overcome such constraints, various models and correction techniques can be employed in photolithography processes.

As illustrated in FIG. 1, the optical model simulates the manner in which light interacts with the photomask and lenses before reaching the wafer, thereby enabling prediction of where distortions may occur. In addition, the resist model predicts how the photoresist will respond to light exposure by taking into account chemical reactions and exposure variations. Such models are essential for understanding and correcting discrepancies between the intended design and the pattern actually printed on the wafer. Meanwhile, in the drawings, the lithography pattern irradiated onto the photoresist layer is determined by the aerial image transmitted through the photomask. The aerial image refers to the image of light that passes through the photomask and is irradiated onto the photoresist layer. Since the aerial image directly determines the etching region of the wafer or other substrate, it represents the image that most closely approximates the desired semiconductor design pattern.

To address the mismatch between the photomask and the aerial image, two fundamental imaging models of lithography—Abbe and Hopkins models—are widely employed. These models are essential in describing how light interacts with the mask and optical system during the lithography process. They simulate the optical behavior of light as it passes through the system and help identify potential distortions that may occur during pattern projection.

The Abbe model is based on coherent imaging theory and explains how diffracted light is projected onto the image plane. The electric field Eimage (x, y; px, py) at the image plane is calculated by integrating the spatial frequencies px and py constrained by the numerical aperture (NA) of the system. This model emphasizes how various diffraction orders contribute to the final image and incorporates wave interference effects and complex amplitudes.

$${E}_{\text{?}} \text{?} = - \frac{M}{{λ}^{2}} \int {\int }_{\text{?}} \sqrt{\frac{\text{?}}{\text{?}}} \text{?} \qquad [ Equation 1 ]$$

$$\text{?} \text{indicates text missing or illegible when filed}$$

Mathematical Formula 1 models the manner in which a wavefront propagates through an optical system. In the formula, T represents the transmission function of the system, and Φ(sₓ, s_{γ}) describes the phase modulation induced by the projection optics. This model provides a detailed explanation of how spatial frequency components within the system's numerical aperture (NA) contribute to the image formed on the wafer. Meanwhile, λ (lambda) denotes the wavelength of light, which generally falls within the extreme ultraviolet (EUV) or deep ultraviolet (DUV) range in lithography and plays a critical role in determining the resolution of the aerial image. cos θ is a value related to the incident angle (θ) of the light, indicating the propagation direction of light within the optical system. It is used in calculations involving refraction and reflection of light and serves as an important factor in the spatial frequency range limited by the system's numerical aperture (NA). Eₒₓ (electric field of object) represents the electric field on the object plane, which corresponds to the light field incident through the photomask and contains both the phase and amplitude information of the light at that position. Eₒₓ plays a central role in the final computation of the aerial image. M (mask function) denotes the function of the photomask, representing the geometric and optical characteristics of the mask pattern. It adjusts the phase and intensity of the light transmitted through the mask and plays a key role in pattern projection during the lithography process. T (transmission function) represents the transmission characteristics of the optical system and defines the propagation properties of lenses and other optical components. This function is related to the physical characteristics of the lenses and describes how the light affects phase and amplitude as it passes through them. Φ (phase term) represents phase modulation in the frequency domain, reflecting the phase change occurring as the light passes through the photomask and lenses. It varies with the spatial frequency components of the system and can influence the quality of the resulting aerial image.

While the Abbe model deals with coherent light, the Hopkins model incorporates partial coherence, which represents a more realistic scenario in modern photolithography. The intensity I(x, y) on the image plane is obtained by integrating the product of the electric field and its complex conjugate over all spatial frequencies within the aperture.

$$I ( x , y ) = \int {\int }_{\text{?}} {I}_{source} ( {p}_{x} , {p}_{y} ) {E}_{image} ( x , y ; {p}_{x} , {p}_{y} ) {E}_{image}^{*} ( x , y ; {p}_{x} , {p}_{y} ) {dp}_{x} {dp}_{y} \qquad [ Equation 2 ]$$

$$\text{?} \text{indicates text missing or illegible when filed}$$

Mathematical Formula 2 represents the image intensity I(x, y) at a specific point (x, y) on the image plane. The image intensity is calculated by integrating over all spatial frequencies px and py within the numerical aperture (NA) of the system. The intensity is determined by the product of the source intensity Isource(px, py), the electric field Eimage(x, y; px, py), and the complex conjugate of the electric field

$${E}_{image}^{*} ( x , y ; {p}_{x} , {p}_{y} ) .$$

This equation reflects the partially coherent characteristics of the light source, and the integration limits are constrained by the NA so that only spatial frequency components within the aperture contribute to image formation.

$$I ( r ) = \int {\int }_{- ∞}^{+ ∞} {I}_{source} ( {p}_{x} , {p}_{y} ) {E}_{image} ( x , y ; {p}_{x} , {p}_{y} ) {E}_{image}^{*} ( x , y ; {p}_{x} , {p}_{y} ) {dp}_{x} {dp}_{y} \qquad [ Equation 3 ]$$

The two equations described above together account for both spatial coherence and partial coherence, thereby explaining the light intensity distribution on the image plane in a lithography system.

Unlike Mathematical Formula 2, Mathematical Formula 3 generalizes the intensity distribution I(r) without restricting the integration limits by the numerical aperture (NA). In this case, the integration extends over the entire spatial frequency domain from −∞ to +∞. This equation is used when the NA does not impose a strong constraint or when broader spatial frequency components are considered. In this situation, the source intensity and the electric field are combined similarly to the complex conjugate of the electric field, thereby taking into account all possible contributions of spatial frequencies to compute the final image intensity.

Together, these two equations describe the relationship among the source intensity, electric field, and final image intensity. Mathematical Formula 2 specifies the limitation imposed by the NA, whereas Mathematical Formula 3 provides a more generalized framework for calculating intensity across all spatial frequencies.

Here, Isource(px, py) represents the intensity distribution of the light source, while the electric field term Eimage includes the complex amplitude and phase factors necessary to model the final image intensity on the wafer. The Hopkins model is critical for simulating the effects of partially coherent light—commonly used in advanced lithography systems—on image fidelity.

In the Hopkins model, the final expression for the image intensity I(r) introduces a mutual coherence function γ(r1 r2), which describes the spatial coherence between two points on the pupil plane. The resulting image intensity is expressed as a convolution of the mutual intensity and the point spread function (PSF) h(r−r2), which characterizes the response of the system to a point light source.

$$I ( r ) = \int {\int }_{- ∞}^{+ ∞} M ( {r}_{1} ) {M}^{*} ( {r}_{2} ) γ ( {r}_{1} - {r}_{2} ) {h}^{*} ( r - {r}_{2} ) {dr}_{1} {dr}_{2} \qquad [ Equation 4 ]$$

The M (mask function), as described earlier, represents the function corresponding to the photomask and expresses the geometric and optical characteristics of the mask pattern. It mathematically models how the geometric pattern designed on the photomask interacts with light, adjusting the phase and intensity of the light transmitted through the mask. In addition, r1 and r2 represent position vectors of two points on the pupil plane. In a lithography system, the pupil plane is a region within the optical system where the propagation of light is controlled before being focused. The position vectors r1 and r2 are used to define spatial coherence between the two points.

By using this equation, a more detailed analysis can be performed on how partial coherence and optical aberrations affect the final printed pattern. Therefore, the Hopkins model is particularly useful for understanding practical lithography processes.

The Abbe and Hopkins models provide a fundamental framework for simulating and understanding optical phenomena in lithography. As feature sizes in semiconductor manufacturing continue to decrease, these models become increasingly important for predicting how light interacts with a photomask and projects the intended pattern onto a wafer. This understanding serves as the basis for implementing advanced correction techniques such as Optical Proximity Correction (OPC).

OPC is a technique designed to compensate for optical distortions predicted by these models by adjusting the photomask design itself. By pre-correcting wavefront distortions, OPC enables the final pattern printed on the wafer to more closely match the intended design. Without OPC, diffraction and other optical limitations can cause features such as lines and edges to deviate from their intended shapes, leading to functional issues in semiconductor devices. Through OPC, the photomask can be modified, thereby enabling more accurate patterning as semiconductor feature sizes continue to shrink.

In conclusion, the Abbe and Hopkins models form the foundation for understanding optical behavior in lithography. These models not only provide insight into how light interacts with photomasks and optical systems but also guide critical corrections such as OPC to ensure that the final wafer pattern matches the original design as closely as possible.

OPC compensates for optical distortions that occur during exposure, thereby allowing the resulting pattern on the wafer to align more accurately with the intended circuit design. Without OPC, diffraction may cause features such as lines and corners to deviate from their intended forms, resulting in distorted printed circuit patterns. Such distortions can lead to functional defects in the fabricated semiconductor devices. However, by using OPC, small corrective distortions can be intentionally added to the photomask to offset these optical effects.

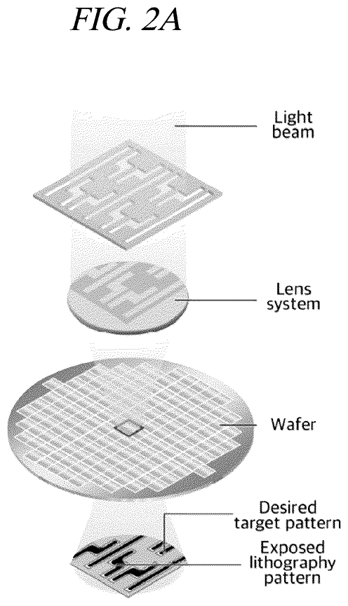

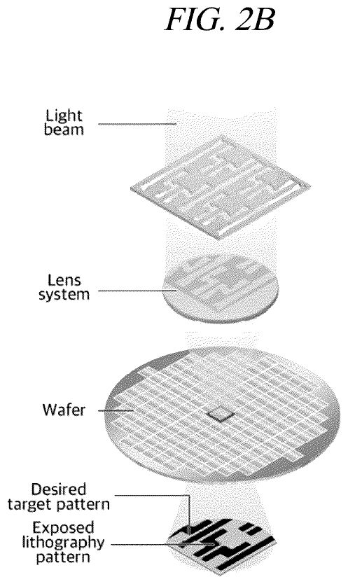

FIGS. 2A and 2B illustrate a general lithography process, comparing lithography results without OPC (shown in FIG. 2A) and lithography results with OPC applied (shown in FIG. 2B).

FIG. 2A depicts a standard process in which light passes through a photomask and lens to project a pattern onto a wafer. When OPC is not applied, noticeable distortions occur in smaller features. In FIG. 2B, where OPC is applied, the printed circuit pattern produced through the corrected photomask matches the original design. In summary, OPC addresses the inherent challenges of optical diffraction and ensures that even the smallest chip features are accurately reproduced.

Meanwhile, in the drawings, the lithography pattern irradiated onto the photoresist layer is determined by the aerial image transmitted through the photomask. The aerial image refers to the image of light that passes through the photomask and is irradiated onto the photoresist layer. Since the aerial image directly determines the etching region of the wafer or other substrate, it represents the image that most closely approximates the desired semiconductor design pattern. Ideally, the aerial image should be identical to the target pattern; however, as shown in FIG. 2A, when a discrepancy occurs between the aerial image and the target pattern, the photomask is corrected—as in FIG. 2B—so that the aerial image becomes as identical as possible to the target pattern. Accordingly, in the present invention, the aerial image generated in the photolithography process can be predicted in advance and used to adjust the photomask so that the resulting pattern matches the target pattern.

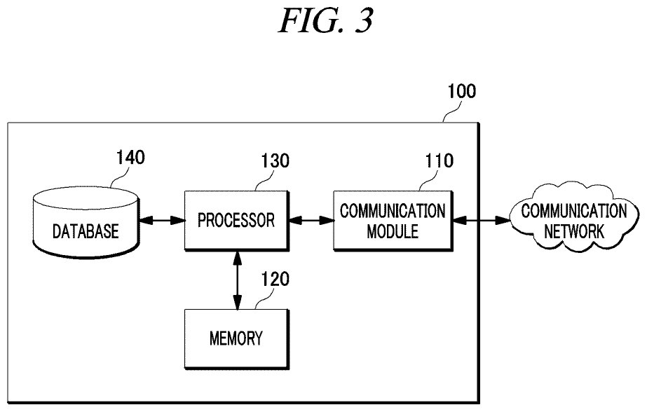

FIG. 3 illustrates an aerial image prediction apparatus according to an embodiment of the present invention.

The aerial image prediction apparatus (100) may include a communication module (110), a memory (120), a processor (130), and a database (140). The aerial image prediction apparatus (100) is configured to predict an aerial image in a semiconductor lithography process, and may be implemented either in the form of semiconductor lithography equipment or as a separate computing device. For example, the aerial image prediction apparatus (100) may be implemented as a computer or portable terminal capable of accessing a network. The computer may include, for instance, a notebook, desktop, or laptop computer, and the portable terminal may be any type of handheld wireless communication device that ensures portability and mobility, such as a smartphone, tablet PC, or smartwatch.

In addition, the aerial image prediction apparatus (100) may be implemented as a server that receives information about a region of interest on a photomask and provides the corresponding aerial image prediction result to an external computing device. The server may operate under cloud computing service models such as Software as a Service (SaaS), Platform as a Service (PaaS), or Infrastructure as a Service (IaaS), and may be deployed in a private cloud, public cloud, or hybrid cloud configuration.

The communication module (110) may include hardware and software necessary for transmitting and receiving signals such as control signals or data signals through wired or wireless connections with other network devices.

The memory (120) may store an aerial image prediction program. The aerial image prediction program is configured to input positional information of a region of interest on a photomask into a learning model based on a physics-informed neural network to predict an aerial image representing the intensity distribution of light irradiated onto a photoresist layer after passing through the region of interest. The learning model based on the physics-informed neural network may include: a fully connected neural network trained to infer a first aerial image corresponding to the positional information of the region of interest; and a physics-informed neural network configured to convert the first aerial image into frequency-domain data through Fourier transformation, apply the data to a mathematical model based on an Abbe model or a Hopkins model to calculate a second aerial image, and update the weights of the fully connected neural network using a loss function representing the difference between the first aerial image and the second aerial image. The memory (120) may include not only volatile storage devices that require power to retain stored information but also magnetic storage media or flash storage media. However, the scope of the present invention is not limited thereto.

The memory (120) may also store separate programs such as an operating system for the processing and control operations of the processor (130) and may further function as temporary storage for data input and output during program execution.

The processor (130) executes the aerial image prediction program (hereinafter referred to as “the program”) stored in the memory (120) and provides functionality for controlling the hardware of the aerial image prediction apparatus (100) according to the execution of the program.

Specifically, when the processor (130) executes the program, it may perform hardware control functions such as managing file systems, memory allocation, network operations, basic libraries, timers, device control (for display, media, input devices, 3D, etc.), and other utility functions.

The processor (130) may include any type of device capable of processing data. For example, it may refer to a hardware-embedded data processing device having physically structured circuits that perform functions represented by code or instructions included in the program. Examples of such hardware-embedded data processing devices include, but are not limited to, microprocessors, central processing units (CPUs), processor cores, multiprocessors, application-specific integrated circuits (ASICs), and field programmable gate arrays (FPGAs). However, the scope of the present invention is not limited thereto.

The database (140) stores or provides data required by the aerial image prediction apparatus (100) under the control of the processor (130). For example, the database (140) may store results generated during the training process of the learning model based on the physics-informed neural network. The database (140) may be included as a component separate from the memory (120) or may be implemented within a designated region of the memory (120).

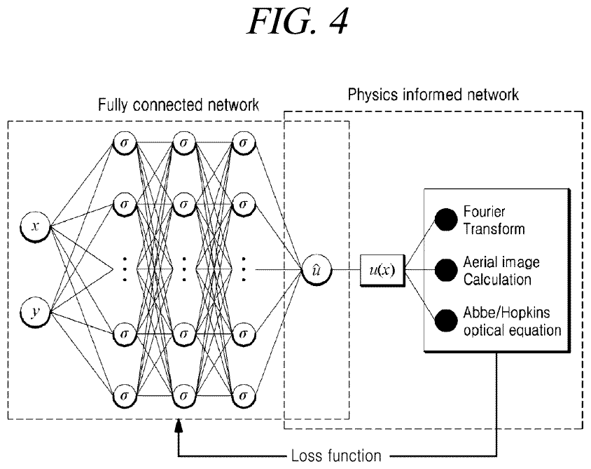

FIG. 4 illustrates the configuration of a learning model based on a physics-informed neural network according to an embodiment of the present invention.

As shown in FIG. 4, the learning model includes a fully connected neural network trained to infer a first aerial image corresponding to the positional information of a region of interest, and a physics-informed neural network configured to convert the first aerial image into frequency-domain data through Fourier transformation, apply the data to a mathematical model based on an Abbe model or a Hopkins model to calculate a second aerial image, and update the weights of the fully connected neural network using a loss function representing the difference between the first and second aerial images.

First, in regard to the fully connected neural network, it is trained based on learning data in which the positional information (x, y) of a region of interest and the corresponding light intensity distribution (I) at that position are matched. That is, when a region of interest on the photomask is specified, the positional information for that area is defined as input data, and the light intensity distribution (I) at the corresponding position, which is output-matched to the input, is defined as output data. Here, the light intensity distribution (I) is interpreted as the intensity distribution of the aerial image. As described above with reference to Mathematical Formulas 1 through 4, the light intensity distribution can be determined by the square of the electric field component.

For the photomask, for example, a GDSII file may be used. The GDSII file is an industry-standard file format for exchanging design data of integrated circuits and contains the geometric design necessary for photomask fabrication. From this GDSII file, polygons representing photomask patterns are extracted. Based on the extracted polygons, a binary mask is generated. The binary mask, expressed as f(x,y), represents the transmission characteristics at spatial coordinates (x, y). This binary mask serves as an important input in the subsequent computational process, particularly when it is transformed into frequency-domain data through Fourier transformation. Once the positional information (x, y) of the region of interest is determined, the pixel value of the photomask or binary mask at each position can be identified. For instance, it can be determined whether each position (x, y) belongs to the interior of a specific pattern type within the photomask. The value of the photomask at each position can thus be defined as input data for training the fully connected neural network.

In addition, the output data for training the fully connected neural network may correspond to the intensity or electric field components of light in the frequency domain. To obtain these values, the binary mask data is subjected to Fourier transformation to compute the spatial frequencies px and py as defined in Mathematical Formulas 1 through 3. The light intensity or electric field values may correspond to those derived from the Abbe or Hopkins models, as described previously with reference to Mathematical Formulas 1 through 4.

Using such training data, the fully connected neural network is constructed to match the input and output data included in the learning dataset. It adjusts weights and biases across multiple layers to learn the relationship between the input and output data. Through this process, the network learns the nonlinear relationship between the positional information (x, y) of the region of interest on the photomask and the light intensity distribution (I) at the corresponding position. Furthermore, by indirectly learning the information in the frequency domain generated through Fourier transformation, the network models the influence of the photomask on the light intensity distribution.

Next, the configuration of the physics-informed neural network will be described.

When the fully connected neural network outputs a first aerial image including the light intensity distribution (I) corresponding to the positional information (x, y) of the region of interest, the physics-informed neural network converts the first aerial image into frequency-domain data through Fourier transformation, applies the frequency-domain data to a mathematical model based on an Abbe model or a Hopkins model to calculate a second aerial image, and updates the weights of the fully connected neural network using a loss function representing the difference between the first and second aerial images.

In particular, the physics-informed neural network is configured such that the physical characteristics of various optical modules included in semiconductor lithography equipment and the physical laws governing light propagation through those optical modules are collectively learned and embedded into the model.

The physics-informed neural network performs a Fourier transformation on the binary mask to convert the data from the spatial domain into the frequency domain. This transformation is essential for applying the principles of Abbe imaging. To this end, as shown in Mathematical Formula 5, a Fourier transformation can be applied to a function f(x). As previously described, the binary mask is expressed as f(x,y), representing the transmission characteristics at spatial coordinates (x, y). For the binary mask f(x,y), a two-dimensional Fourier transformation is applied as shown in Mathematical Formula 5 to generate frequency-domain data F(u,v). Through this process, the positional information in the spatial domain is transformed into specific frequency components in the frequency domain. Moreover, this enables analysis of the frequency components of the mask pattern and computation of the frequency response of the pattern.

$$F [ f ( x ) ] = \frac{1}{\sqrt{2 π}} {\int }_{- ∞}^{∞} f ( x ) {e}^{- i ω x} dx \qquad [ Equation 5 ]$$

After the data is converted into the frequency domain using the Fourier transformation, it is applied to a mathematical model based on the Abbe model or the Hopkins model, as described in Mathematical Formulas 1 through 4, to calculate a second aerial image that includes the actual light intensity distribution.

In the Abbe or Hopkins model described in Mathematical Formulas 1 through 4, the light intensity distribution is calculated using the pattern types of the photomask. The photomask represents the fine circuits of a semiconductor and includes various pattern types corresponding to different parts of each circuit. Each pattern type is combined in a modular manner to form the overall fine circuit.

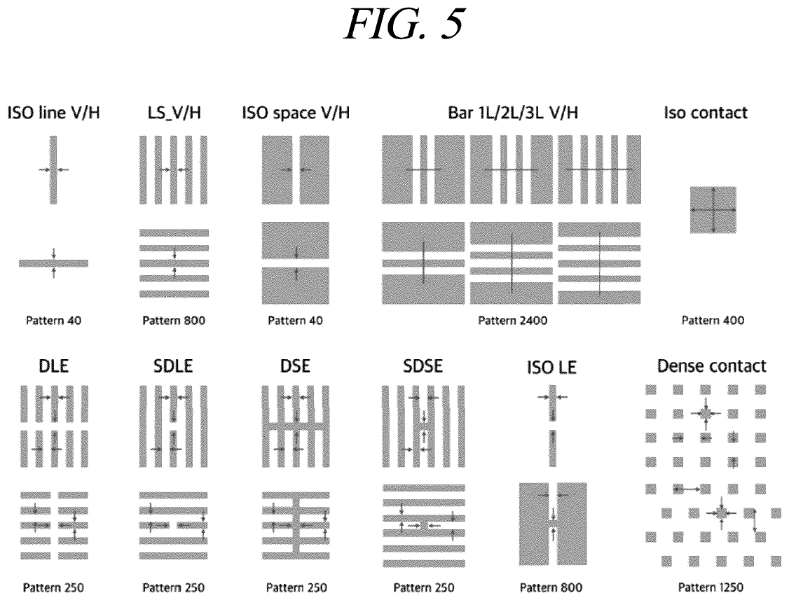

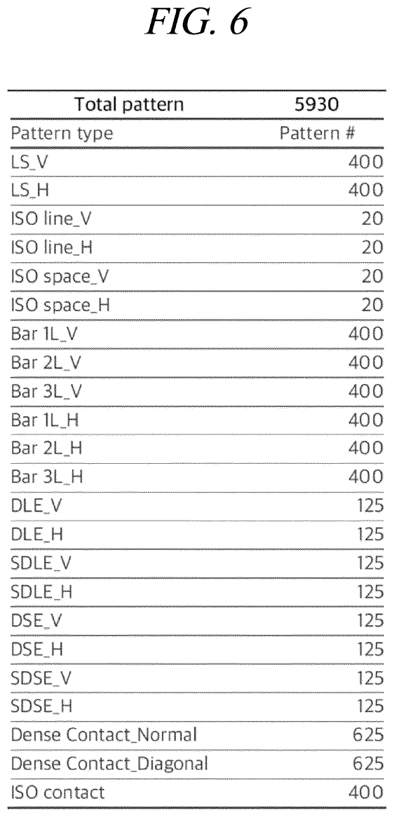

FIGS. 5 and 6 are diagrams for explaining pattern types of a photomask applied in an embodiment of the present invention.

For each pattern type, a label including identification information and detailed design information is stored in a matching manner. The identification information corresponds to a classification system that distinguishes each pattern type, while the detailed design information includes coordinate information specifying the location of each pattern type on the photomask, size information such as line width, spacing, or density, and structural characteristics such as the orientation (vertical or horizontal), pattern density of each pattern type (e.g., Line-Space, Dense Contact).

As shown in FIGS. 5 and 6, each pattern type is classified into various categories such as ISO line (ISO line V/H), Line-Space (LS V/H), ISO space (ISO space V/H), Bar, and Dense Contact, among others. In addition, the pattern types may include both vertical (V) and horizontal (H) orientations as well as isolated (ISO) structures. These patterns may be further subdivided into different density configurations such as “1L,” “2L,” and “3L,” where “L” represents a line.

For example, the label for each pattern type may include the following information:

LS_V (Line-Space Vertical) and LS_H (Line-Space Horizontal) are used to evaluate the effects of vertical and horizontal patterning.

Bar 1L V (1-line bar vertical) and Bar 2L H (2-line bar horizontal) are used to analyze multi-line configurations.

Dense Contact Normal and Dense Contact Diagonal pattern types are created to evaluate the behavior of densely packed contact holes oriented in different directions.

The pattern type may also vary depending on detailed design information such as the critical dimension (CD) or spacing. That is, even when the pattern type is the same, the measured critical dimensions, such as the line width or the spacing between lines, can be set differently. Accordingly, for simulation purposes, the label for each pattern type is supplemented with additional contextual information regarding the critical dimension or spacing. For example, a pattern type labeled Bar 1L V includes detailed design information such as line width and spacing, enabling the simulation to accurately account for the geometric configuration when modeling optical exposure and resist behavior.

By matching labels containing identification information and detailed design information for each pattern type and applying them to the Abbe model or the Hopkins model, it becomes possible to predict how variations in the critical dimensions or spacing of each pattern type affect the printed pattern on the wafer. Consequently, the simulation can account for a wide range of potential lithography challenges, from line collapse to bridging in dense configurations.

In the present invention, a total of 5,930 labeled pattern types were prepared for testing. Each label includes both identification information for distinguishing pattern types and detailed design information, as described above. Therefore, even when the pattern type is the same, variations exist depending on the detailed design parameters. For example, in the case of Dense Contact pattern types such as Dense Contact Normal and Dense Contact Diagonal, separate labels are assigned so that both the normal and diagonal configurations are considered in the simulation.

Referring again to FIG. 4, to quantify the difference between the first aerial image and the second aerial image, a Mean Squared Error (MSE) loss function is employed. This loss function is essential for evaluating the performance of the neural network. Based on the calculated loss, the weights of the fully connected neural network are updated to minimize the loss, and this optimization step is crucial for improving the model's prediction accuracy.

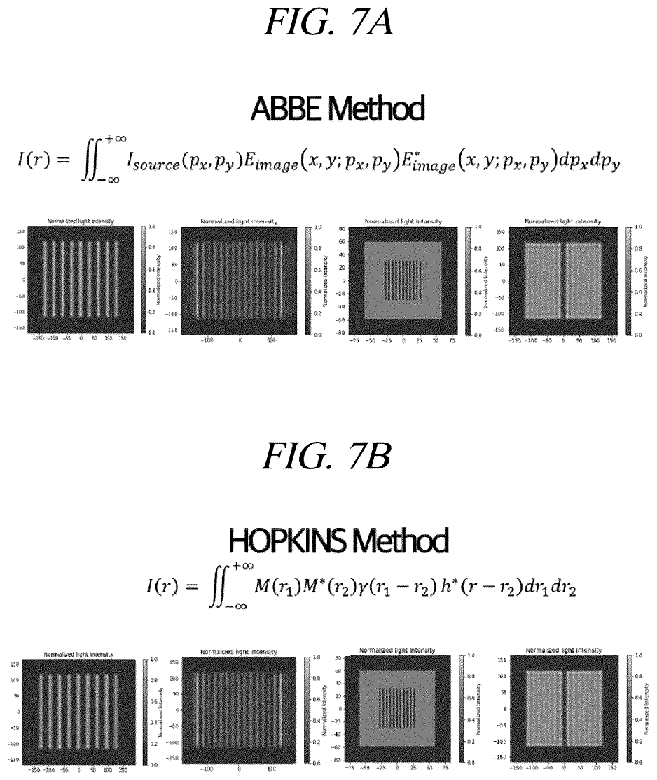

Finally, the second aerial image can be visualized as shown in FIGS. 7A and 7B.

FIGS. 7A and 7B illustrate examples of aerial images output through the aerial image prediction apparatus according to an embodiment of the present invention.

In FIG. 7A, the second aerial image is based on the Abbe model, which focuses on diffraction effects that are critical in coherent imaging systems. This model simulates the light intensity distribution for various fundamental lithographic patterns such as line-space patterns. The results of the Abbe model simulation visually depict how light is distributed across the wafer for each pattern. As shown in FIG. 7A, light intensity varies depending on line spacing and pattern density, with the highest intensity observed at the edges of the lines.

In FIG. 7B, the second aerial image is based on the Hopkins model, which integrates partial coherence, offering a more realistic representation of modern lithography systems. This model allows for more realistic simulation by taking partial coherence effects into account. The Hopkins model simulation results demonstrate how partial coherence affects the final image, providing deeper insight into how light interacts with the pattern.

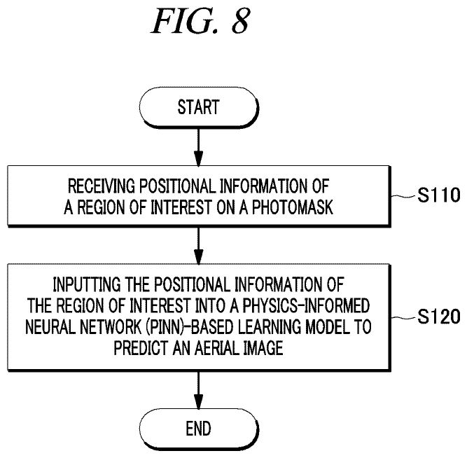

FIG. 8 is a flowchart illustrating an aerial image prediction method according to an embodiment of the present invention.

In operation S110, the aerial image prediction apparatus receives positional information of a region of interest on the photomask.

Next, in operation S120, the positional information of the region of interest is input into the physics-informed neural network (PINN)-based learning model, which predicts an aerial image representing the light intensity distribution projected onto the photoresist layer after transmission through the region of interest.

In this case, the PINN-based learning model includes a fully connected neural network (FCNN) trained to infer a first aerial image corresponding to the input positional information of the region of interest, and a physics-informed neural network configured to update the weights of the FCNN using a loss function that calculates the difference between the first and second aerial images. The physics-informed neural network generates the second aerial image by converting the first aerial image into frequency-domain data through a Fourier transform and applying a mathematical model based on the Abbe model or Hopkins model.

The training method according to an embodiment of the present invention can also be implemented in the form of a computer-readable recording medium containing program modules or other computer-executable instructions. The computer-readable medium may include any available medium accessible by a computer, encompassing both volatile and nonvolatile, removable and non-removable media. Furthermore, the computer-readable medium may include computer storage media that store information such as computer-readable instructions, data structures, program modules, or other data, using any method or technology for storage.

Although the apparatus and method of the present invention have been described with reference to specific embodiments, all or part of their components or operations can be implemented using a computer system having a general-purpose hardware architecture.

The foregoing description of the invention is merely illustrative. Those skilled in the art will understand that various modifications and changes can be made without departing from the technical spirit or essential features of the present invention. Therefore, the embodiments described above are to be understood as illustrative rather than restrictive in every respect. For example, components described as being implemented in a single form may be distributed, and conversely, components described as distributed may be implemented in a combined form.

The scope of the present invention should therefore be defined by the appended claims, rather than by the foregoing detailed description, and all modifications or variations derived from the meanings and equivalents of the claims should be construed as being included within the scope of the invention.

### DESCRIPTION OF REFERENCE NUMERALS

100: Aerial image prediction apparatus
110: Communication module
120: Memory
130: Processor
140: Database

What is claimed is:

1. An aerial image prediction apparatus for predicting an aerial image in a semiconductor lithography process, comprising:
a memory in which an aerial image prediction program is stored; and
a processor configured to execute the program stored in the memory,
wherein the aerial image prediction program is configured to:
input positional information of a region of interest on a photomask into a physics-informed neural network (PINN)-based learning model to predict an aerial image representing a light intensity distribution irradiated onto a photoresist layer after passing through the region of interest,
and the PINN-based learning model comprises:
a fully connected neural network (FCNN) trained to infer a first aerial image corresponding to the input positional information of the region of interest; and
a physics-informed neural network configured to calculate a second aerial image by converting the first aerial image into frequency-domain data through a Fourier transform and applying a mathematical model based on an Abbe model or a Hopkins model, and to update the weights of the fully connected neural network using a loss function that calculates a difference between the first and second aerial images.

2. The aerial image prediction apparatus according to claim 1,
wherein the fully connected neural network is trained based on training data in which the positional information of the region of interest is matched with the light intensity distribution at the corresponding position,
and the light intensity distribution is frequency-domain data.

3. The aerial image prediction apparatus according to claim 1,
wherein the mathematical model of the physics-informed neural network uses information regarding pattern types that classify parts of circuits included in the photomask,
and each pattern type is matched with a label including identification information of the pattern type and detailed design information, the detailed design information comprising coordinate information of each pattern type, line width of each pattern type, spacing of each pattern type, orientation of each pattern type, or pattern density of each pattern type.

4. An aerial image prediction method for predicting an aerial image in a semiconductor lithography process, performed by an aerial image prediction apparatus, comprising:
receiving positional information of a region of interest on a photomask; and
predicting an aerial image representing a light intensity distribution irradiated onto a photoresist layer after passing through the region of interest, by inputting the positional information of the region of interest into a physics-informed neural network (PINN)-based learning model,
wherein the PINN-based learning model comprises:
a fully connected neural network trained to infer a first aerial image corresponding to the input positional information of the region of interest; and
a physics-informed neural network configured to calculate a second aerial image by converting the first aerial image into frequency-domain data through a Fourier transform and applying a mathematical model based on an Abbe model or a Hopkins model, and to update the weights of the fully connected neural network using a loss function that calculates a difference between the first and second aerial images.

5. The aerial image prediction method according to claim 4,
wherein the fully connected neural network is trained based on training data in which the positional information of the region of interest is matched with the light intensity distribution at the corresponding position,
and the light intensity distribution is frequency-domain data.

6. The aerial image prediction method according to claim 4,
wherein the mathematical model of the physics-informed neural network uses information regarding pattern types that classify parts of circuits included in the photomask,
and each pattern type is matched with a label including identification information of the pattern type and detailed design information, the detailed design information comprising coordinate information of each pattern type, line width of the pattern type, spacing of the pattern type, orientation of the pattern type, or pattern density of the pattern type.

7. A non-transitory computer-readable recording medium on which a computer program is recorded,
the computer program being configured to execute the aerial image prediction method according to claim 4.
